(19) United States
(12) Patent Application Publication
(10) Pub. No.: US 2004/0235199 A1
(43) Pub. Date: Nov. 25, 2004

(54) Method for fabricating a nanoarray using the self-assembly of supramolecules and staining of metals

(76) Inventors: Hee Tae Jung, Daejeon (KR); Ki Young Kwon, Gyeongsangbuk-do (KR); Su Rim Lee, Gangwon-do (KR)

Correspondence Address: INTELLECTUAL PROPERTY / TECHNOLOGY LAW, PO BOX 14329, RESEARCH TRIANGLE PARK, NC, 27709, US

(21) Appl. No.: 10/850,241

(22) Filed: May 20, 2004

(30) Foreign Application Priority Data
May 22, 2003 (KR) 10-2003-0032514
Jun. 5, 2003 (KR) 10-2003-0036531

(51) Int. Cl. H01L 21/00; G03G 9/00

(52) U.S. Cl. 438/1

(57) ABSTRACT

A method for forming a nanopattern of supramolecules, which includes the steps of: forming a thin film of supramolecules on a substrate; self-assembling the supramolecules by annealing to form regular structures; selectively staining the formed regular structures with a metal; and etching the metal-selectively stained thin film to remove a portion of the thin film, which was not stained with the metal. Such method enables the fabrication of nanoarray devices in which bioreceptors are attached to the formed nanopattern of supramolecules on the substrate.

### CROSS-REFERENCE TO RELATED APPLICATIONS

This application claims priority under 35 USC 119 of Korean Patent Application No. 10-2003-0032514 filed May 22, 2003 and Korean Patent Application No. 10-2003-0036531 filed Jun. 5, 2003.

### BACKGROUND OF THE INVENTION

1. Field of the Invention

The present invention relates to a method for forming nanometer- or smaller sized patterns, which comprises the steps of forming a thin film of supramolecules on a substrate, inducing the self-assembly of the supramolecules by annealing to form regular structures, selectively staining the regular structures with a metal, and etching the metal-stained thin film. The invention also relates to a method for fabricating nanoarray structures, which comprises the attachment of bioreceptors to the formed nanopattern of supramolecules.

2. Background of the Related Art

Formerly, surface pattern formation has been realized by photolithography using a polymeric thin film as photoresist, but the realization of a nanometer-sized, highly precise patterns by this method encounters many difficulties, because of limitations in the wavelength of light capable of being used, the provision of an apparatus and technology suitable for such light wavelength, and the resolution of the polymer itself.

Since 1990, there have been attempts to use new photoresists in photolithography and to increase the resolution of patterns using light of a shorter wavelength. Further, new patterning techniques, such as nanopatterning techniques using soft lithography, started to appear. Such techniques have advantages in that they allow inexpensive patterning and continuous operations. However, their resolution limit is at a level of about 100 nm and it is difficult to expect a further increase in resolution leading to an increase in integration density.

Meanwhile, Korean patent No. KR 10/263671B1 discloses a method for forming nanometer-sized fine patterns using supramolecules as a patterning material. In this method, the thickness of fine pattern remaining in a groove is ensured by using an additional buffer layer in order to provide a margin for excessive etching, and a spacer is formed on the buffer layer in order to reduce the size of the groove. However, the number of process steps is large, and the pattern size is limited to a level of several tens of nanometers.

Korean patent publication No. KR 2002-0089528A discloses a small-sized, self-assembled structure for forming devices that are widely used in the microelectronic industry. The self-assembly method disclosed in this application provides the ability to form an array in association with a surface, but it is impossible for the self-assembly itself to determine the position of a device-forming material within the boundary along the surface. Thus, in forming a device within the boundary along the surface, an individual positioning technique is necessary, and a suitable positioning technique is used with the self-assembly method, to form a structure capable of functioning as an individual part in integrated electronic circuits. The positioning technique permits the determination of the boundary of a structure by lithography, direct formation methods or other positioning techniques, so that a patterned substrate is formed and a device is assembled on the substrate by self-assembly.

A self-assembled structure can be combined with a structure formed by conventional chemical or physical deposition techniques, and an integrated electronic circuit can comprise integrated optical parts. The self-assembled structure can be formed using nanoparticle dispersion in such a manner that the desired structure is obtained by adjustment according to a material surface condition and temperature and concentration conditions. A linker, one end of which is bound to the substrate surface and the other end of which is chemically bound to nanoparticles, is used, and selective binding using the linker can be used to lead to a self-assembly process of nanoparticles.

Another selective binding method is the use of natural interaction, such as electrostatic and/or chemical interaction, to induce the self-assembly process of nanoparticles, in which the nanoparticles are deposited in micropores such that they are positioned within the boundary defined by porous regions. The micropores can be found in certain materials, such as inorganic oxides or two-dimensional organic crystals, or suitable micropores can be formed by, for example, ion milling or chemical etching. However, this approach is disadvantageous in that the process is complex, and spacing between patterns remains at a level of several tens to hundreds of nanometers.

Korean patent publication No. 2003-0023191A discloses a method for forming nanometer-sized ultrafine patterns using a self-assembled monomolecular layer. This method comprises the steps of forming a layer of aromatic imine molecules with substituted end groups on a substrate, selectively binding and cutting the substituent groups of the aromatic imine molecule layer, and hydrolyzing the resulting aromatic imine molecule layer, thereby allowing the pattern to be formed in a short time. However, the pattern size according to this method still remains at a level of several tens of nanometers.

Additionally, dip-pen nanolithography has been reported, in which the tip of an atomic force microscope is stained with surfactant molecules having a chemical affinity for a solid substrate, and nanofeatures are formed on the substrate, much like the tip of an ink pen would write with ink on paper (Piner, R. D. et al., Science, 283:661, 1999). This technique has an advantage in that it is possible to achieve high-resolution patterns, e.g., as small as 5 nm special resolutions, using an ultra-sharp tip. However, this technique has a problem in that the pattern must be separately formed in a serial processing manner, so that a long time is required to achieve the desired features, thus making it difficult to directly apply this technique to mass production.

As described above, although various methods, including photolithography and etching methods using ultraviolet light and X-ray, are being introduced, the formation of sub-100 nm patterns has reached limitations. In an attempt to solve the associated problems, bottom-up methods are being widely studied as a substitute for existing top-down methods.

The bottom-up methods are based on the formation of microstructures by the self-assembly of molecules, and among such basic technologies, a method of analyzing the microstructure of supramolecules by a scanning electronic microscope has been reported (Hudson, S. D. et al., Science, 278:449, 1997) and it has been reported that the orientation of supramolecules varies depending on the surface property of a substrate (Jung, H. T. et al., Macromolecules, 35:3717, 2002). However, these publications describe only the microstructure analysis of supramolecules and the orientation of supramolecules, respectively.

Studies are being conducted on forming sub-100 nm patterns using block copolymers, e.g., involving the formation of regular patterns using block copolymers and the formation of dot-shaped patterns using metal staining (Park, M. et al., Science, 276:1401, 1997). However, the patterns formed by such methods remain at a level of several tens of nanometers or larger size, since they rely on the molecular chain of the polymers. Also, the use of the block copolymers entails problems in that the aspect ratio of the pattern formed is not large, the structure of the resultant thin film is complex, and it is difficult to impart a structural orientation to the thin film.

Meanwhile, microarray protein chips are of great importance in current researches on diagnostic proteomics. An early array technology (U.S. Pat. No. 5,143,854) that utilized a photolithographic technique for a polypeptide array on the surface of a substrate has recently generated new interest and is the subject of ongoing work. In particular, increasing importance is being attached to development of a microarray-type format in various immunoassays, including antigen-antibody pairs and enzyme-liked immunosorbent assays.

However, it is not easy to make the protein array smaller than DNA arrays or to integrate or arrange the protein array into a substantial format having increased sensitivity. The lattice pattern of DNA oligonucleotides can be produced on the surface of a substrate by photolithography, but in the case of a protein consisting of several hundreds of amino acids, more highly integrated lattice patterns with high density (for example, an antibody can comprise about 1,400 amino acids) are required for the exact diagnosis of diseases on the substrate surface. It is not easy to satisfy this requirement.

Another problem with proteins is that they can easily lose their three-dimensional structure during manipulation under denaturing conditions (Bernard, A. et al., Anal. Chem., 73:8, 2001), so that the manipulation of proteins has many limitations.

A solution to such problems requires that the proteins be processed in such manner that they can be arrayed at high resolution without loss of their three-dimensional structure. Towards this objective, various approaches, including inkjet printing, drop-on-demand technology, microcontact printing, and soft lithography have been proposed. However, arrays formed by such methods are characterized by spacing dimensions of several tens of micrometers to several millimeters, and no techniques have been found that produce highly integrated diagnostic protein nanoarrays having a high density character, while maintaining the three-dimensional structure of the protein.

### SUMMARY OF THE INVENTION

Accordingly, the present inventors have conducted intensive studies to develop a simpler method for forming a several nanometer-sized ultrahigh density pattern, and have discovered a technique that is useful for forming groove- or pillar-shaped patterns of several nanometers or smaller in size, using supramolecular self-assembly and selective metal staining, to produce a formed pattern to which bioreceptors or other ligands or moieties can be attached.

The present invention provides a method for forming supramolecular pattern of several nanometers or less size, using supramolecular self-assembly and selective metal staining.

The present invention also provides a method for forming a nanopattern on a substrate or a metal thin film on the substrate, which comprises the step of etching the substrate or the metal thin film, using a nanopattern of supramolecules as a mask.

The invention also provides a method for fabricating a separation membrane, which includes binding a plurality of the nanopatterned substrates, obtained by the previously described techniques of the invention, to each other.

The invention further contemplates a method for fabricating a bio-nanoarray, and the bio-nanoarray product of such method, in which the method involves attaching a bioreceptor to the nanopattern obtained by the previously described techniques of the invention.

Other aspects, features and advantages of the invention will be more fully apparent from the ensuing disclosure and appended claims.

### BRIEF DESCRIPTION OF THE DRAWINGS

FIG. 1 schematically shows a self-assembly process of supramolecules. FIG. 1a shows that disc-shaped dendrimers (1) and fan-shaped supramolecules (2) are self-assembled into cylindrical structures (3) which are then arranged into three-dimensional hexagonal structures (4). FIG. 1b shows that cone-shaped molecules (5) are self-assembled into spherical structures (6) which are arranged into three-dimensional regular structures (7).

FIG. 2 schematically shows a method for forming a nanopattern for the fabrication of a bio-nanoarray according to one embodiment of the present invention.

FIG. 3 is a transmission electron microscope photograph showing that supramolecules are self-assembled into hexagonal pillar-shaped regular structures.

FIG. 4 is a scanning electron microscope photograph showing a nanopattern formed according to the present invention.

FIG. 5 is a schematic diagram showing a process for fabricating a nanopattern of a metal thin film.

FIG. 6 is a schematic diagram showing the fabrication of a bio-nanoarray by binding of biomolecules to a nanopattern of a metal thin film.

### DETAILED DESCRIPTION OF THE INVENTION, AND PREFERRED EMBODIMENTS THEREOF

The present invention provides a method for forming a nanopattern of supramolecules, which in one embodiment comprises the steps of: (a) forming a thin film of supramolecules on a substrate, (b) self-assembling the supramolecules by annealing to form regular (e.g., geometrically regular, morphologically regular) structures; (c) selectively staining the formed regular structures with a metal; and (d) etching the metal-selectively stained thin film to remove a portion of the thin film, which was not stained with the metal. Thin films in accordance with the invention include films that have a thickness that does not exceed about 5 mm, which may by way of example include films having a thickness in a range of from about 5 nm to about 5 mm, such as films with a thickness of from about 0.01 μm to about 500 μm.

The method of fabricating the nanopattern can additionally comprise, before step (a), the step of modifying a surface of the substrate in order to adjust the orientation of the pattern structures. The modification of the substrate surface is preferably performed by forming on the substrate surface, a metal or non-metal thin film, a self-assembled monolayer (SAM) or other thin films suitable for the end purpose of the pattern. Examples of substrates that can be used in the practice of the present invention include substrates formed of silicon, glass, molten silica, polymers and any other suitable materials.

The supramolecules used in the broad practice of the invention may be of any suitable self-assembling type. In one embodiment of the present invention, the supramolecules comprise a compound of the following formula (1):

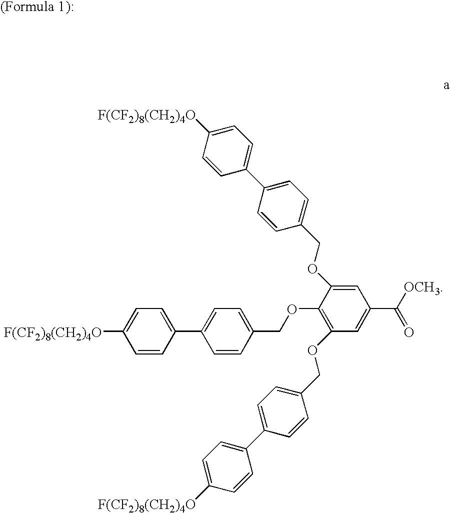

Examples of the self-assembling supramolecules include, without limitation, disc-shaped dendrimers, fan-shaped supramolecules, and stick-chain shaped or cone-shaped molecules. An example of the fan-shaped supramolecules includes a compound of the following formula (2). An example of the disk-shaped supramolecules includes a compound of the following formula (3). An example of the cone-shaped supramolecules includes a compound of the following formula (4):

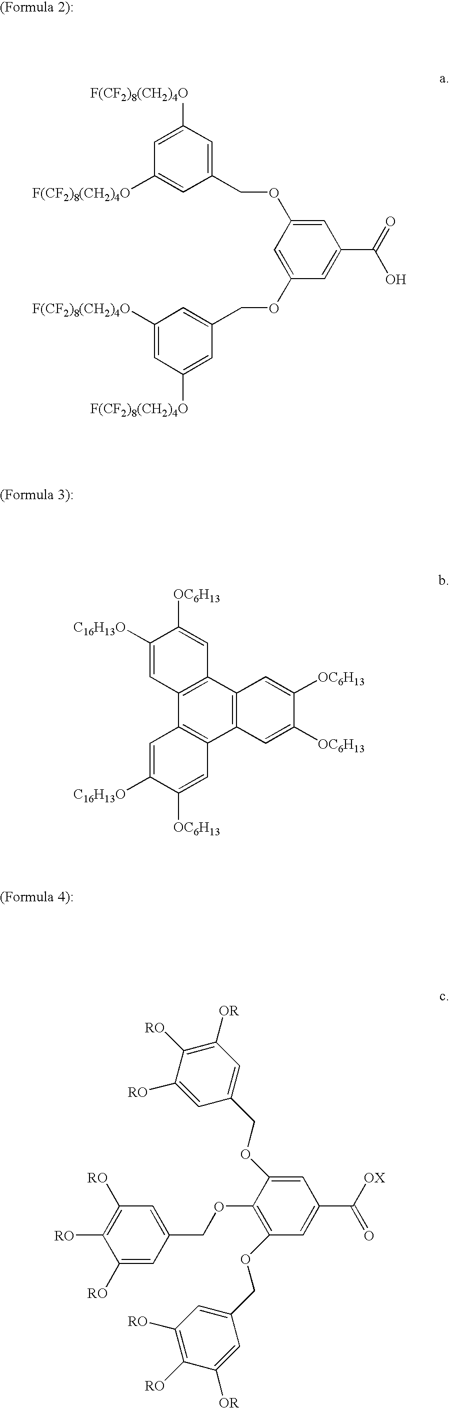

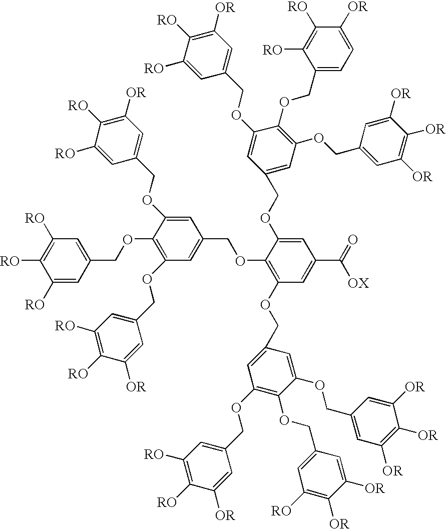

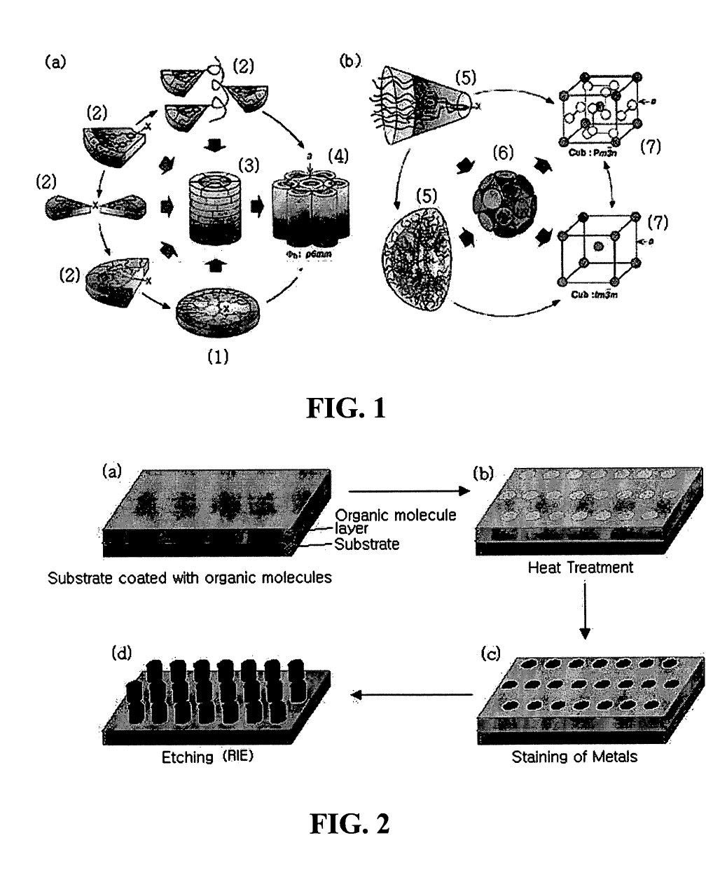

Such supramolecules are formed into a regular structure by physical secondary binding, such as by van der Waals forces, unlike polymers in which the monomeric units are covalently bonded. Such supramolecules are self-assembled by any suitable processing or environmental conditions, e.g., the provision of suitable temperature or concentration conditions, external magnetic field or electric field conditions, etc, to form certain fine structures. The supramolecules of formula (1) used in the present invention correspond to the fan-shaped dendrimers. As shown in FIG. 1a, such fan-shaped dendrimers are self-assembled into plate-shaped structures (1), which are then assembled into pillar-shaped structures (3), which are formed into a three-dimensional hexagonal structure (4). In addition, as shown in FIG. 1b, the cone-shaped supramolecules (5) are self-assembled into spheres (6), which are then arranged into a three-dimensional regular structure (7).

In one embodiment of the present invention, the thin film in step (a) of the process described in paragraph [00031] hereof, is preferably formed by spin-coating, rubbing, solution spreading or other suitable technique that forms a thin firm on the surface, and annealing in step (b) is preferably performed by heating the surpamolecules above their liquid crystal transition temperature and then cooling them slowly. The metal staining in step (c) preferably is performed by selectively staining the central portion of the thin film with ruthenium tetroxide (RuO₄), and step (d) preferably is performed by a reactive ion etching (RIE) method.

In another aspect, the present invention provides a method for forming a nanopattern on a substrate or a metal thin film, which comprises the step of etching the substrate or the metal thin film using the nanopattern of supramolecules formed by the above-described method as a mask. In this method, the etching of the substrate or metal thin film preferably is performed by ion etching and/or ion milling.

In still another aspect, the present invention provides a method for fabricating a separation membrane, which comprises binding a plurality of nanopattern of the substrate formed by the above method, to each other.

In yet another aspect, the present invention provides a method for forming a nanopattern of a magnetic metal thin film for high-density recording materials, the method comprising the steps of: (a) forming a magnetic metal thin film on a substrate; (b) forming a thin film of self-assembling supramolecules on the magnetic metal thin film; (c) self-assembling the supramolecules by annealing to form a regular structure; (d) selectively staining the formed regular structure with a metal; (e) etching the metal-selectively stained thin film to remove a portion of the thin film, which was not stained with the metal, thereby fabricating the nanopattern of supramolecules; and (f) etching the magnetic metal thin film using the nanopattern of supramolecules as a mask. In this method, the magnetic metal can be of any suitable type, but preferably comprises a metal selected from the group consisting of Fe, Ni, Co, Cr, Pt, and alloys thereof.

In one embodiment, the present invention provides a method for fabricating a bio-nanoarray, which comprises the step of attaching a bioreceptor to the groove-shaped substrate nanopattern. The invention also provides bio-nanoarrays fabricated by the above method, in which a bioreceptor is bound to a groove-shaped substrate nanopattern.

In yet another aspect, the present invention provides a method for fabricating bio-nanoarray, which comprises the steps of: (a) forming a thin film of a material having an affinity for a bioreceptor on a substrate; (b) forming a thin film of self-assembling supramolecules on the thin film having an affinity for the bioreceptor; (c) self-assembling the supramolecules by annealing to form a regular structure; (d) selectively staining the formed regular structure with a metal; (e) etching the metal-stained thin film to remove a portion of the thin film, which was not stained with the metal, thereby forming a nanopattern of supramolecules; (f) etching the thin film of the material having an affinity for the bioreceptor, using the nanopattern of supramolecules as a mask, to form a pillar-shaped metal nanopattern; and (g) binding the bioreceptor to the nanopattern of the material having an affinity for the bioreceptor. Also, the present invention provides a bio-nanoarray fabricated by the above method, in which bioreceptor is bound to the nanopattern of the material having an affinity for the bioreceptor.

In the practice of such aspect of the present invention, the bioreceptor can be of any suitable type, but preferably comprises a bioreceptor selected from the group consisting of proteins, peptides, lipids, oligonucleotides, PNAs, amino acids, DNAs, enzymatic substrates, ligands, cofactors, carbohydrates and RNAs. The step of binding the protein to the nanopattern preferably is performed by attaching the bioreceptor to the nanopattern of the substrate using a binding aid. The binding aid can be of any suitable type, but preferably is a chemical material having an aldehyde, amine or imine group attached to a carbon group end. More specifically, the binding of the bioreceptor to the nanopattern may be performed by binding an aldehyde group to the substrate surface, attaching an amine group to the end of the bioreceptor, and then binding the bioreceptor by inducing the amine-aldehyde reaction.

As used herein, the term “bio-nanoarray” is defined to include biochips and biosensors, in which a bioreceptor that binds to or reacts with a biomaterial is attached to the nanopattern.

The present invention is described in more detail hereinafter.

According to one preferred embodiment of the present invention, supramolecules are first dissolved in a tetrahydrofuran (THF) solvent at a suitable concentration, e.g., a 1-wt % concentration, and the resulting solution is applied on a substrate to form a thin film of supramolecules. In forming the thin film of supramolecules, spin-coating, rubbing, or solution spreading is preferably used. In this embodiment, a silicon wafer is used as the substrate, and no modification of the substrate surface is carried out (FIG. 2a).

Thereafter, the supramolecules are heated above their liquid crystal phase transition temperature such that they are self-assembled. Such supramolecules may for example have a liquid crystal phase transition temperature of about 230° C., and they are heated to suitable temperature, e.g., to about 240° C., and then cooled slowly. Thus, the supramolecules are self-assembled into pillar-shaped microstructures (FIG. 2b).

The self-assembly process of supramolecules by annealing according to a preferred embodiment of the present invention will now be described.

The properties of supramolecules can be modified by annealing, and starting materials suitable for annealing include supramolecules produced by pyrolysis. Additionally, the supramolecules used as the starting materials can undergo at least one preheating step under different conditions. The pre-heating treatment of supramolecules formed by laser pyrolysis improves their crystallinity and removes contaminants such as atomic carbon, and in some instances the pre-heating treatment can change the stoichiometry of the supramolecules, e.g., by combining additional oxygen, or atoms from gaseous or nongaseous compounds. The supramolecules preferably are heated in an oven or other thermal environment providing uniform heating. The treatment conditions are generally mild so that a significant amount of sintered particles is not produced. Thus, the heating temperature preferably is lower than the melting point of both the starting material and the product. If the thermal treatment involves a change in composition, the size and shape of the molecules can be changed even at mild heating temperatures.

Self-assembled structures are formed on the surface of the material/substrate or within the surface. The self-assembled structures are positioned within boundaries in the form of positioned islands, and each of the structures can serve as an element of circuits or devices having a plurality of elements. Specifically, each of the structures may constitute an element of integrated electronic circuits, and examples of such elements include electrical parts, optical devices and photonic crystals.

In order to form a structure within a predetermined boundary, a process of defining the boundary of the structure and a separate self-assembly process are required for the formation of the self-assembled structure. The process of defining the boundary of the structure utilizes an external force. It is generally not possible to define the structure boundary by the self-assembly process itself. When a composition/material is bound, its self-assembly is based on the natural sensing function of the composition/material, which causes natural ordering in the resulting structure. Generally, although the positioning process can be conducted before or after the self-assembly process, the nature of the treatment steps can also indicate certain orders. The net result is a self-assembled structure having a region within the boundary, which is covered with nanoparticles, and also a region outside the boundary, which is not covered with the nanoparticles. The process of defining the boundary is linked to the self-assembly process, by either activating the self-assembly process in the boundary or inactivating the region outside the boundary. Generally, to carry out the activating process or the inactivating process, the application of an external force is necessary.

The fact that supramolecules are self-assembled into a regular structure on a substrate can be confirmed by a transmission electron microscope. As an example, a sample was fabricated according to the method of the present invention, and a photograph of the sample taken by the transmission electron microscope is shown in FIG. 3. The photograph in FIG. 3 suggests that the supramolecules are self-assembled into hexagonal pillar-shaped regular structures.

The step of staining the regular structures of self-assembled supramolacules with a metal according to a preferred embodiment of the present invention will now be described.

First, RuO₄ solution and a substrate coated with a thin film of supramolecules are maintained in a glass container with the solution not being in direct contact with the substrate. In this process, while Ru metal in the RuO₄ solution is diffused into the gas phase, the supramolecular thin film on the substrate is stained with the Ru metal. The stained Ru metal chemically reacts selectively with certain portions of the thin film.

Although RuO₄ is illustratively employed in the example, as a staining agent useful in the practice of the present invention, osmium tetroxide (OsO₄) or any other metals capable of selectively staining the structures formed by supramolecules may alternatively be used.

According to a preferred embodiment of the present invention, as the substrate coated with the supramolecular thin film is subjected to the metal staining process and then an etching process, a given portion of the supramolecular thin film on the substrate is removed so that nanopatterned devices are ultimately obtained. In the etching process, any suitable etching method that is conventionally used in a semiconductor device fabrication process may be used, without limitation. For example, the etching process can be performed by using an etching solution, such as a KCN-KOH mixture solution or HF aqueous solution, or by reactive ion etching (RIE) or ion milling.

The nanopattern formed according to the preferred embodiment of the present invention as described above can be used as surface substrates in forming a desired array by reacting any of various bioreceptors with the nanopattern. Such technique is capable of producing biochips of high integration density and small size.

Generally, biochips are fabricated by linking biomolecules directly to a substrate or linking biomolecules to the substrate by means of linker molecules. For example, when bioreceptors (e.g., DNAs, antibodies or enzymes) are attached to the surface of a solid substrate in order to produce DNA chips, protein chips or protein sensors, an aldehyde group is bound to the substrate surface and an amine group is bound to the bioreceptor, so that the bioreceptor then can be attached to the substrate surface by the chemical bonds between amine and aldehyde, thereby producing the desired bio-devices.

A method for fabricating a DNA chip as a bioarray according to one embodiment of the present invention comprises the step of attaching a previously prepared probe to the surface of a solid substrate by a spotting method. In this case, an amine group-bound probe is dissolved in 1× to 7×, preferably 2× to 5×, and more preferably 3×SSC buffer solution (0.45 M NaCl, 15 mM C₆H₅Na₃O₇, pH 7.0), and then spotted to an aldehyde-bound substrate by a microarrayer. The probe then is fixed to the substrate by the reaction between the aldehyde and the amine. The concentration of the probe preferably is greater than 10 pmol/μl, more preferably greater than 50 pmol/μl, and most preferably greater than 100 pmol/μl. The amine group bound to the probe preferably is reacted with the aldehyde group bound to the substrate at a humidity of 70-90%, and more preferably 80%, for a suitable period of time, e.g., 4-8 hours, more preferably 5-7 hours, and most preferably about 6 hours, so that the probe is fixed to the substrate.

The dot-shaped structures can be converted into their reverse structures. For this purpose, silicon or silicon nitride (SiN) can be deposited on the substrate having the dot-shaped structures formed thereon, so that portions outside the structures are filled with the silicon or silicon nitride. Thereafter, the original dot-shaped structures are removed so that they are converted into hole-shaped structures.

### EXAMPLES

The present invention will hereinafter be described in further detail by reference to illustrative examples. It will however be apparent to a person skilled in the art that these examples can be modified into various different forms, and the present invention therefore is not limited to or by the examples. These examples are presented to further illustrate the present invention.

### Example 1

### Synthesis of Supramolecules

Supramolecules of formula (1) were synthesized by a process as shown in reaction scheme (1) below. The result of scanning electron microscopic analysis on such supramolecules confirmed that the supramolecules were regular cylindrical structures of nanometer- or smaller size.

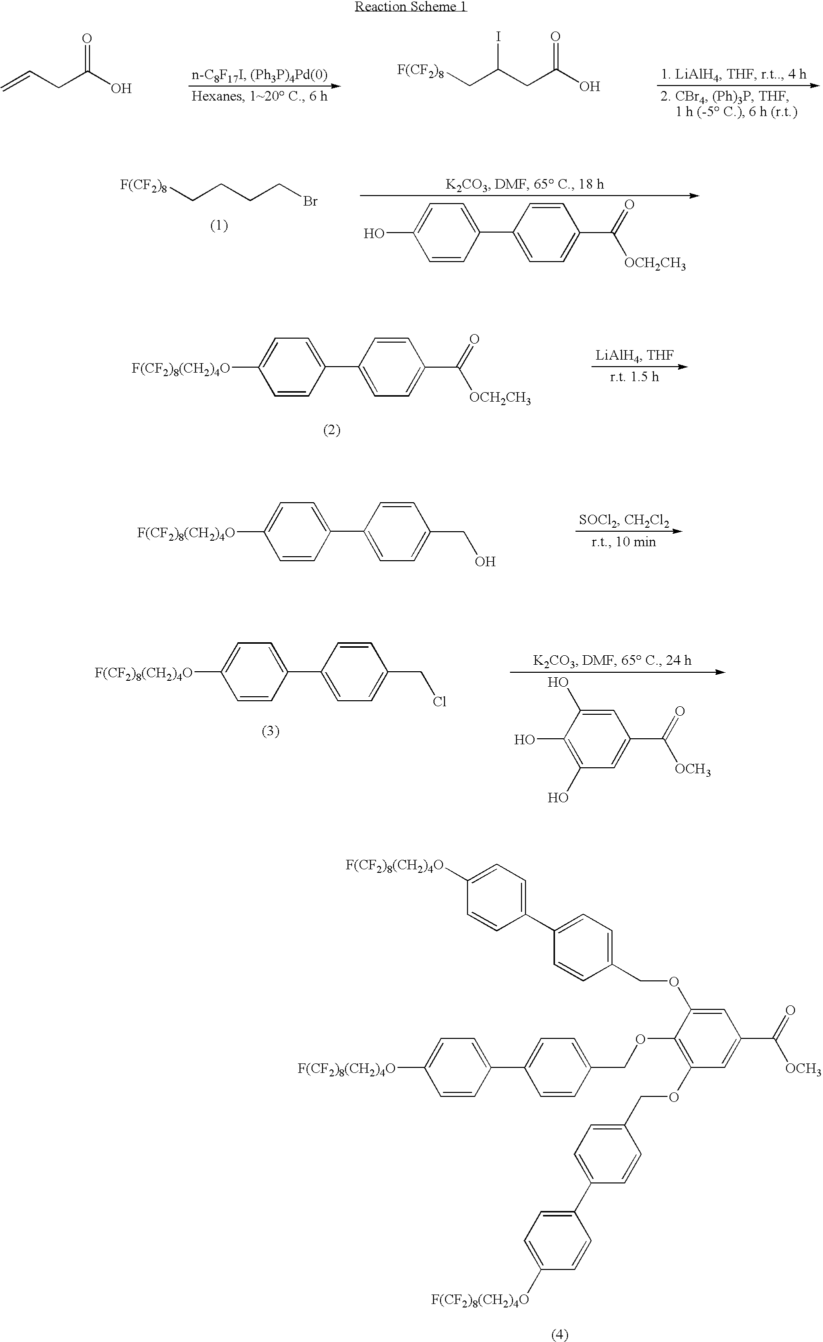

### Example 2

### Modification of Substrate Surface

In various embodiments of the process of the present invention, a silicon wafer was used as a substrate. If necessary, metal, non-metal or other thin films can be formed on the substrate surface.

### Example 3

### Formation of Thin Film of Supramolecules

The supramolecules synthesized in Example 1 were dissolved in tetrahydrofuran (THF) solvent. The resultant solution was spin-coated on the silicon wafer of Example 2 to form a thin film as shown in FIG. 2a. In this Example, the spin-coating was performed at 2,000-3,000 rpm for 10-30 seconds. During this spin-coating, the thickness of the thin film can be suitably changed.

### Example 4

### Annealing

The thin film of supramolecules was heated to 240° C. and then cooled slowly, to form regular microstructures of the type shown in FIG. 2b. These supramolecules are self-assembled at 240° C., it being appreciated that the self-assembly temperature conditions can vary according to the specific type(s) of supramolecules used. At a temperature of 240° C., the supramolecules used in the example have a sufficient mobility for their self-assembly, and are self-assembled into the most stable structures, which in the case of these supramolecules were three-dimensional structures in which cylinders are arranged in a hexagonal shape.

### Example 5

### Staining with Ruthenium Tetroxide (RuO₄)

Since the supramolecules can be stained with RuO₄ selectively at their central portions, the supramolecules were exposed to RuO₄ for several minutes, to stain chemically their central portions with Ru metal, in the manner illustratively shown in FIG. 2c.

When the supramolecules are exposed to RuO₄, the Ru metal is diffused into the air so that the supramolecular thin film is stained with the Ru metal. The Ru metal chemically reacts with certain reactive groups (e.g., ether bonds, alcohols, benzene rings, and amines), and the supramolecules are stained with the Ru metal at their portions corresponding to the central portions of the supramolecular cylinders.

The staining metal alternatively can be or include any other suitable metals, depending on the types of supramolecules involved. For example, osmium tetroxide (OsO₄) chemically reacts with reactive groups such as carbon double bonds, alcohols, ether bonds, and amines.

### Example 6

### Etching

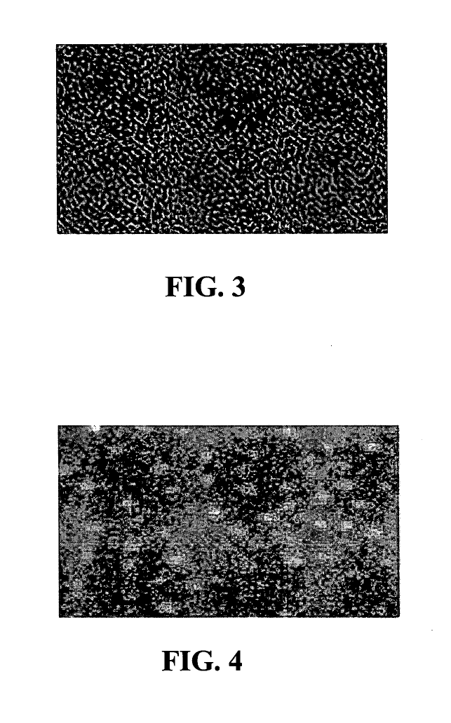

Thereafter, the metal-stained thin film of supramolecules was subjected to an etching process, so that dot-shaped structures remained at the central portions of the supramolecular cylinders due to the difference in etch rate between the staining metal and the supramolecules, as illustratively depicted in FIG. 2d. FIG. 4 is a scanning electron microscope photograph showing the configuration of such dot-shaped structures. In this example, the etching was carried out using CF₄ gas for about 100 seconds. The etching time may be widely varied in practice, depending on the specific apparatus employed, the nature of the staining metal, the type of supramolecules, and other factors. Thus, a test step for setting etching conditions should be carried out, as a general procedure.

### Example 7

### Method of Forming a Nanopattern on the Substrate

The substrate was etched using the nanopattern of supramolecules obtained as described in Examples 1-6, as a mask, thereby forming a nanopattern on the substrate. In this illustrative embodiment, an intermediate layer was not formed on the substrate. However, if another thin film layer is formed between the substrate and the supramolecular thin film, the formed dot-shaped nanopattern can serve as a mask in a subsequent etching step. In such instance, the portions of the film on which the dot pattern was formed are not etched, while the intermediate thin film layer whose surface was exposed is etched, so that the pattern formed by the supramolecules is transferred to the intermediate thin film layer. This result can be varied depending on the material used in the intermediate thin film layer. If the intermediate thin film layer is a metal thin film layer, it can be etched by ion milling. If it is a non-metal or an organic thin film layer, it can be etched by reactive ion etching and ion milling. Etching conditions can therefore be established within the skill of the art, in accordance with the properties of each thin film layer.

### Example 8

### Fabrication of a Bio-nanoarray by Attachment of a Bioreceptor to a Groove-shaped Nanopattern

In order to attach a bioreceptor to the groove-shaped substrate nanopattern formed in Example 7, an aldehyde group is bound to the substrate and an amine group is bound to the end of the bioreceptor, after which the bioreceptor is attached to the substrate by an amine-aldehyde reaction.

### Example 9

### Fabrication of a Bio-nanoarray by Attachment of a Bioreceptor to a Pillar-shaped Nanopattern

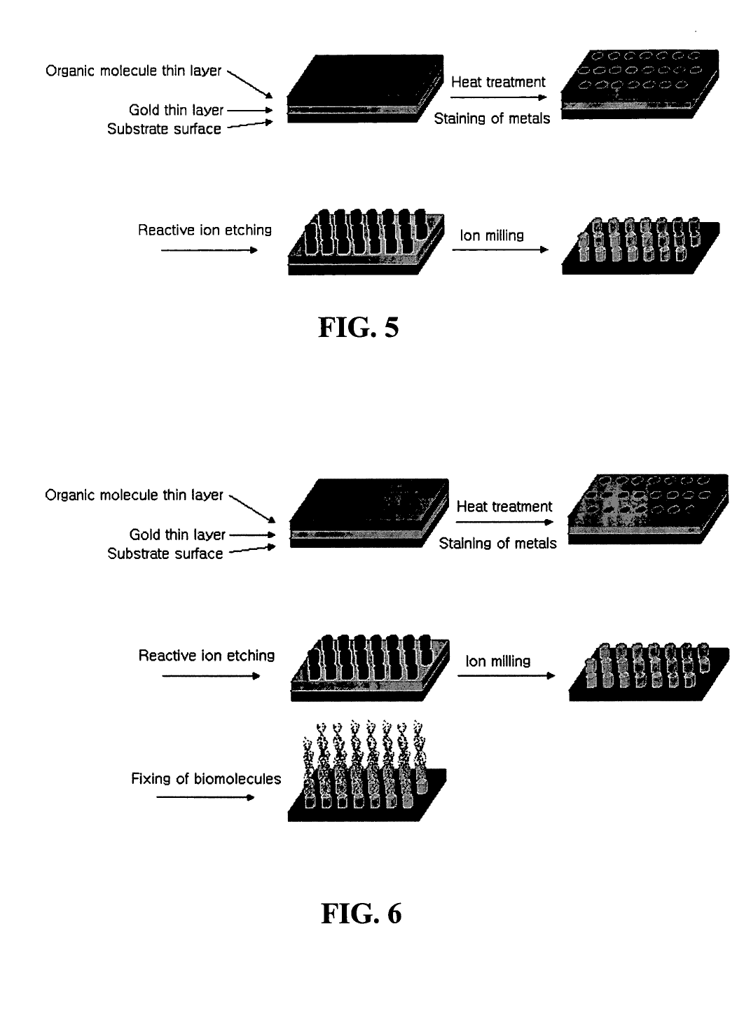

A thin film of a material having an excellent affinity for a bioreceptor was formed on the substrate, and then, the procedures of Examples 1-6 were performed to form a nanopattern of supramolecules. Ion milling was carried out using the nanopattern of suparmolecules as a mask, to fabricate a nanopattern of the thin film of the material having an affinity for the bioreceptor as schematically depicted in FIG. 5.

In this Example, gold (Au) was used as the material having an affinity for the bioreceptor. Gold can bind selectively to a bioreceptor (e.g., peptides and proteins) containing a thiol (—SH) group. Using this property of gold, biomolecules can be bound selectively to the gold nanopatterns, thereby fabricating high-density bio-nanoarray devices as schematically shown in FIG. 6.

It will be apparent from the foregoing description that the present invention achieves a substantial advance in the art, in the provision of a method for fabricating a bio-nanoarray by binding the bioreceptor to the groove- or pillar-shaped pattern of nanometer or smaller size formed using the supramolecular self-assembly and selective metal staining techniques described herein.

What is claimed is:

1. A method for forming a nanopattern of supramolecules, which comprises the steps of:
(a) forming a thin film of supramolecules on a substrate;
(b) self-assembling the supramolecules by annealing to form regular structures;
(c) selectively staining the formed regular structures with a metal; and
(d) etching the metal-selectively stained thin film to remove a portion of the thin film, which was not stained with the metal.

2. The method of claim 1, further comprising the step of modifying the substrate surface so as to adjust orientation of pattern structures, before the step (a).

3. The method of claim 2, wherein the step of modifying the substrate surface is performed by forming a metal and non-metal, organic thin film on the substrate surface.

4. The method of claim 1, wherein the supramolecules comprise molecules selected from the group consisting of disc-shaped dendrimer fan-shaped supramolecules and cone-shaped supramolecules.

5. The method of claim 4, wherein the supramolecules comprise compounds of the following formula (1):

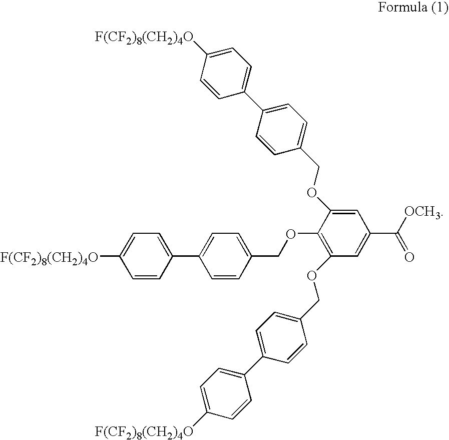

6. The method of claim 1, wherein step (b) comprises heating the supramolecules above their liquid crystal transition temperature and then cooling them.

7. The method of claim 1, wherein step (c) comprises selectively staining the central portion of the thin film with ruthenium tetroxide (RuO₄).

8. A method for forming nanopattern on a substrate or a metal thin film, which comprises the step of etching the substrate or the metal thin film using the nanopattern of supramolecules formed by the method of claim 1.

9. A method for fabricating a separation membrane, which comprises binding a plurality of substrate nanopatterns formed by the method of claim 8, to each other.

10. A method for forming a nanopattern of a magnetic metal thin film for high-density recording materials which comprises the steps of:
(a) forming a magnetic metal thin film on a substrate;
(b) forming a thin film of self-assembling supramolecules on the magnetic metal thin film;
(c) self-assembling the supramolecules by annealing to form a regular structure;
(d) selectively staining the formed regular structure with a metal;
(e) etching the metal-selectively stained thin film to remove a portion of the thin film, which was not stained with the metal, to yield a nanopattern of supramolecules; and
(f) etching the magnetic metal thin film using the nanopattern of supramolecules as a mask.

11. The method of claim 10, wherein the magnetic metal comprises a metal material selected from the group consisting of Fe, Ni, Co, Cr, Pt, and alloys thereof.

12. A method of fabricating a bio-nanoarray, which comprises the step of attaching a bio-material to a groove-shaped substrate nanopattern fabricated by the method of claim 8.

13. A bio-nanoarray fabricated by the method of claim 12, in which a bioreceptor is bound to a groove-shaped substrate nanopattern.

14. The bio-nanoarray according to claim 13, wherein the bioreceptor is bound to the groove-shaped substrate nanopattern by a chemical compound having an aldehyde, amine or imine group attached to a carbon group end.

15. A method for fabricating a bio-nanoarray, which comprises the steps of:
(a) forming a thin film of a material having an affinity for a bioreceptor on a substrate;
(b) forming a thin film of self-assembling supramolecules on the thin film having an affinity for the bioreceptor;
(c) self-assembling the supramolecules by annealing to form a regular structure;
(d) selectively staining the formed regular structure with a metal;
(e) etching the metal-stained thin film to remove a portion of the thin film, which was not stained with the metal, thereby forming a nanopattern of supramolecules;
(f) etching the thin film of the material having an affinity for the bioreceptor, using the nanopattern of supramolecules as a mask, to form a pillar-shaped metal nanopattern; and
(g) binding the bioreceptor to the nanopattern of the material having an affinity for the bioreceptor.

16. The method of claim 15, wherein the supramolecules comprise compounds of the following formula (1).

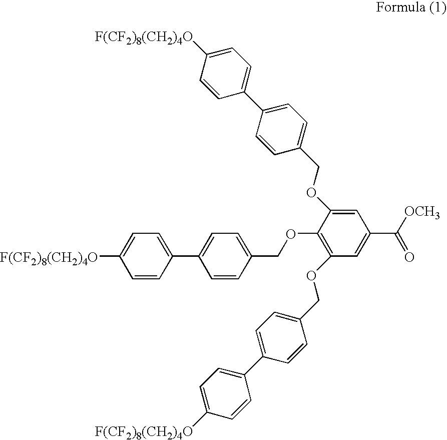

17. The method of claim 16, wherein the step of etching the thin film of the material having an affinity for the bioreceptor to form the pillar-shaped nanopattern comprises an etching technique selected from the group consisting of ion etching and ion milling.

18. The method of claim 17, wherein the material having an affinity for a bioreceptor comprises a metal.

19. The method of claim 15, wherein the metal comprises gold (Au).

20. A bio-nanoarray fabricated by the method of claim 15, in which a bioreceptor is bound to the pillar-shaped nanopattern of the material having an affinity for the bioreceptor.
